(19) United States
(12) Patent Application Publication
(10) Pub. No.: US 2016/0293956 A1
(43) Pub. Date: Oct. 6, 2016

(54) HYBRID CARBON NANOTUBE AND GRAPHENE NANOSTRUCTURES

(71) Applicant: THE REGENTS OF THE UNIVERSITY OF CALIFORNIA, Oakland, CA (US)

(72) Inventors: Wei Wang, Newport Beach, CA (US); Shirui Guo, Riverside, CA (US); Cengiz S. Ozkan, San Diego, CA (US); Mihrimah Ozkan, San Diego, CA (US)

(73) Assignee: The Regents of The University of California, Oakland, CA (US)

(21) Appl. No.: 15/034,352

(22) PCT Filed: Nov. 5, 2013
(86) PCT No.: PCT/US2013/068554

§ 371 Date: May 4, 2016

(51) Int. Cl. H01M 4/587; H01G 11/86; H01M 4/133; H01M 10/0525; H01M 4/66; H01M 4/36; H01M 4/04; H01M 4/1393; C01B 31/04; C23C 16/26; C23C 16/02; C23C 14/18; C23C 14/30; C23C 28/00; C23C 14/04; H01G 11/36

(52) U.S. Cl. CPC H01M 4/587; H01G 11/36; H01G 11/86; H01M 4/133; H01M 10/0525; H01M 4/661; H01M 4/366; H01M 4/0428; H01M 4/1393; C01B 31/0453; C23C 16/26; C23C 16/0209; C23C 16/0281; C23C 14/18; C23C 14/30; C23C 28/32; C23C 28/34; C23C 14/04; H01G 11/02

(57) ABSTRACT

A binder-free hybrid carbon nanotube and graphene nanostructure can be formed via a two-step chemical vapor deposition process. The method can include forming at least one graphene layer onto a surface of a conductive substrate by chemical vapor deposition temperature using a first mixture of methane and hydrogen and growing a plurality of carbon nanotubes onto the surface of the at least one graphene layer by chemical vapor deposition using a second mixture of ethylene and hydrogen to form the binder-free hybrid carbon nanotube and graphene nanostructure.

### TECHNICAL FIELD

This document relates generally to hybrid carbon nanotube and graphene nanostructures and, in particular, to hybrid carbon nanotube and graphene nanostructures for use in energy devices.

### BACKGROUND

The two main types of energy devices can include energy storage devices and energy generating devices. Examples of the energy storage devices can include electrochemical capacitors and batteries. Examples of the electrochemical capacitors can include an electric double layer capacitor and a redox capacitor. The electric double layer capacitor can use an activated carbon as a polarizable electrode and can utilize an electric double layer formed at an interface between a pore surface of the activated carbon and an electrolytic solution. The redox capacitor can use a transition metal oxide, whose valence continuously changes, and an electrically-conductive polymer which can be doped. Moreover, two main types of the batteries can include a secondary battery, which can be charged and discharged by utilizing intercalation and chemical reactions of active materials, and a primary battery, which is not rechargeable after being discharged once.

### OVERVIEW

Energy devices can include carbonaceous materials, for example, as part of an electrode. The carbonaceous materials can exhibit advantageous physical and chemical properties. For example, carbonaceous materials can exhibit increased conductivity, electrochemical stability, and increased surface area as compared to other materials. Graphene, which is a two dimensional carbonaceous material, can provide advantageous electrical and mechanical properties.

Previous approaches have incorporated carbonaceous materials into electrodes. In particular, the previous approaches include combining carbonaceous materials with a binder (e.g., a polymer binder) to form a mixture. The mixture can be casted onto conductive substrates, such as copper, nickel, and aluminum, etc. However, incorporating binder can limit the performance of the electrode. For example, an electrode including the binder can limit the performance of active material due to the relatively poor electrical and thermal conductivity caused by the contact between active material and the binder.

Various examples of the present disclosure can provide a hybrid carbon nanotube and graphene nanostructure that is substantially free from a binder. The present disclosure provides a method for forming the hybrid carbon nanotube and graphene nanostructure. For example, the method can include a two-step chemical vapor deposition process. The present disclosure provides growing pillar or columnar carbon nanotubes on a graphene layer deposited on a conductive substrate.

The hybrid carbon nanotube and graphene nanostructures of the present disclosure can provide many advantages over other energy devices including carbonaceous materials. The hybrid carbon nanotube and graphene nanostructures can have an increased surface area and have unique electrical properties that can be used for various applications, such as energy storage, biochemical sensing and three dimensional interconnected networks.

The present disclosure can provide a binder-free technique for preparing electrodes including the hybrid carbon nanotube and graphene nanostructures that can be used in, for example, lithium ion batteries. In an example, the hybrid carbon nanotube and graphene nanostructures can be incorporated into an electrode, for example, of a lithium ion battery. The graphene layer can act as a barrier layer that can prevent or minimize alloying of the conductive substrate. In an example, the graphene layer can act as a passivation layer that can prevent or minimize oxidation and corrosion of the conductive substrate. Preventing or minimizing oxidation and corrosion can enhance the electrochemical stability of the electrode. The hybrid carbon nanotube and graphene nanostructures of the present disclosure can provide a seamless connection between the graphene and the pillar carbon nanotubes and provide an active material-current collector with increased integrity. Increasing the integrity of the active material-current collector can facilitate charge transfer.

In one example, the present disclosure provides a binder-free technique for forming the hybrid carbon nanotube and graphene nanostructure. For example, the binder-free technique can include a two-step chemical vapor deposition process. The first step can include forming the graphene layer onto a conductive substrate and the second step can include growing pillar carbon nanotubes on a surface of the graphene layer.

In one example, the present disclosure provides a lithium ion battery including the hybrid carbon nanotube and graphene nanostructures of the present disclosure can exhibit a reversibly capacity of about 900 milliampere hour per gram (mAh g⁻¹). In an example, the lithium ion battery including the hybrid carbon nanotube and graphene nanostructures of the present disclosure can minimize fading of capacity. For example, approximately 99 percent (%) retention with 100% Coulombic efficiency over 250 cycles.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally a cross-section of a hybrid nanostructure.

FIG. 2 illustrates generally a cross-section of a battery including a hybrid nanostructure.

FIG. 3 illustrates generally a flow diagram of a method of forming the hybrid nanostructure.

FIG. 4A illustrates a copper foil.

FIG. 4B illustrates a hybrid nanostructure.

FIG. 5A illustrates a scanning electron micrograph (SEM) image of the hybrid nanostructure of FIG. 4B.

FIG. 5B illustrates a top view SEM image of a conductive substrate after a graphene layer has been deposited.

FIG. 5C illustrates a top view SEM image of a hybrid nanostructure.

FIG. 5D illustrates a cross-sectional view SEM image of FIG. 5C.

FIG. 5E illustrates a close-up view of the SEM image in FIG. 5D.

FIG. 5F illustrates a high resolution transmission electron microscopy (HRTEM) of the hybrid nanostructure.

FIG. 6 illustrates a Raman spectra of the hybrid nanostructure.

FIG. 7 illustrates a voltage profile of a lithium ion battery.

FIG. 8 illustrates a voltage profile of the lithium ion battery.

FIG. 9 illustrates cycling performance and Coulombic efficiency of the lithium ion battery.

FIG. 10 illustrates the rate performance of the lithium ion battery

FIG. 11A illustrates a top view low magnification SEM image of the cycled hybrid nanostructure.

FIG. 11B illustrates a top view high magnification SEM image of the cycled hybrid nanostructure.

FIG. 12 illustrates a comparison of the Raman spectra before and after cycling for the hybrid nanostructure.

### DETAILED DESCRIPTION

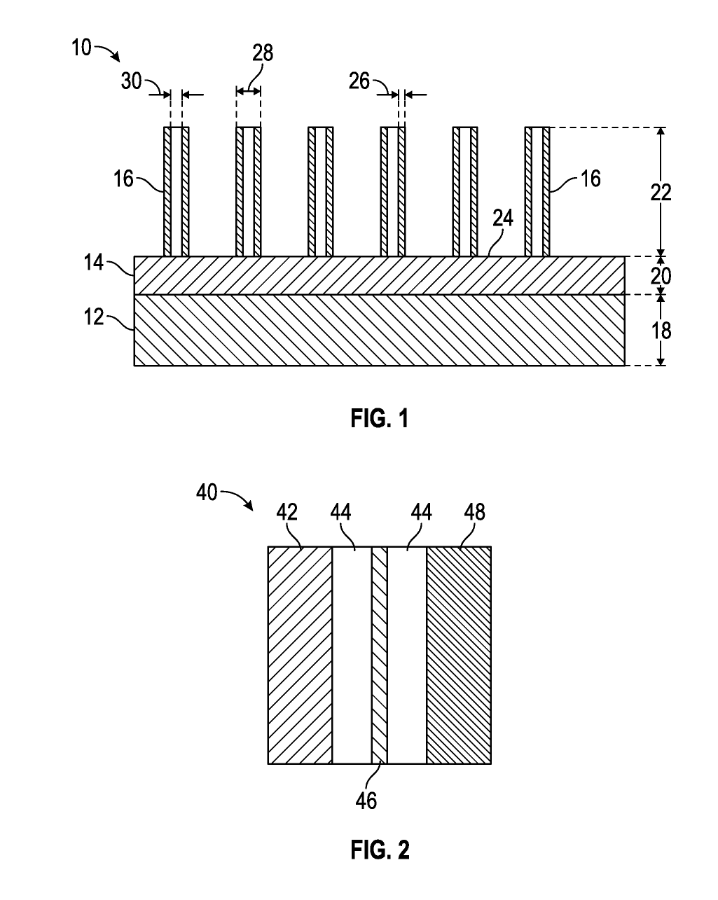

FIG. 1 illustrates generally an example of a hybrid carbon nanotube and graphene nanostructure 10 (also referred to interchangeably as “hybrid nanostructure 10” and “binder-free hybrid carbon nanotube and graphene nanostructure”). In an example, the hybrid nanostructure 10 illustrated in FIG. 1 can be used as an electrode, such as an anode, in a lithium ion battery. The hybrid nanostructure 10 can include a conductive substrate 12, a graphene layer 14, and a plurality of pillar carbon nanotubes 16. The hybrid nanostructure 10 can be substantially free of a binder. “Substantially” as the term is used herein means completely or almost completely; for example, the hybrid nanostructure 10 that is “substantially free” of the binder either has none of the binder or contains such a trace amount that any relevant functional property of the hybrid nanostructure 10 is unaffected by the presence of the trace amount.

In an example, the conductive substrate 10 can be chosen from at least one of copper, nickel, aluminum, platinum, gold, titanium, and stainless steel. In one example, the conductive substrate 10 can be copper. The conductive substrate 10 can have a thickness 18 within a range of about 0.5 micrometers (μm) to about 1000 μm. In one example, the thickness 18 can be about 20 μm.

The hybrid nanostructure 10 can include a graphene layer 14 comprising one or more graphene layers. As discussed herein, the graphene layer 14 can be deposited onto the conductive substrate 12. In an example, the graphene layer 14 can include twenty graphene layers or less. In another example, the graphene layer can include three graphene layers or less. A graphene layer thickness 20 can be single layer, double layer, and up to twenty layers. The thinner the graphene layer thickness 20, the higher the capacitance.

The hybrid nanostructure 10 can include a plurality of carbon nanotubes 16. The plurality of carbon nanotubes 16 can be grown on a top surface 24 of the graphene layer 14. The plurality of carbon nanotubes 16 can have an average height 22 of about 100 μm to about 10000 μm. In an example, the height 22 of the plurality of carbon nanotubes 16 can be about 50 μm. The average height 22 of the plurality of carbon nanotubes can be relevant to a loading mass of active materials on the conductive substrate 12. The average height can be tailored by controlling the growth time. For battery applications, such as lithium ion batteries, the height 22 can be in the range of about 10 μm to about 500 μm. If the height 20 is greater than 500 μm, the charge/ion transfer can decrease.

In an example, the plurality of carbon nanotubes 16 can have an average outer diameter 28 of about 8 nanometers (nm) to about 15 nm. In an example, the plurality of carbon nanotubes 16 can have an average inner diameter 30 of about 5 nm to about 50 nm and a wall thickness 26 of about 1 layer to about 50 layers. Having a smaller wall thickness 26 can increase the total surface area of the hybrid nanostructure.

As discussed herein, the hybrid nanostructure 10 can be used as an electrode. The hybrid nanostructure 10 of the present disclosure can provide advantages over other electrodes, and in particular, over pillar graphene nanostructures grown via a one-step chemical vapor deposition process versus the two-step chemical vapor deposition process disclosed herein. In an example, the graphene layer 14 can act as a current collector. In an example, the graphene layer 14 can act as a buffer layer that can facilitate an electrical connection between the plurality of carbon nanotubes 16 to the conductive substrate 12.

Further, the graphene layer 14 can increase the chemical-mechanical stability of the electrode by minimizing oxidation and electrochemical degradation of the conductive substrate 12. For example, when copper is used as the conductive substrate 12, copper oxide can form on a surface of the copper substrate. The copper oxide can be unstable in electrolytes and can deteriorate between the interface between current collector (e.g., copper substrate) and active materials, which can degrade the overall stability of the electrodes in the system. Thus, the graphene layer 14 can minimize the formation of oxidation and thus minimize the degradation of the conductive substrate 12.

FIG. 2 illustrates generally a cross-section of a battery 40 including the hybrid carbon nanotube and graphene nanostructure 10. In an example, the battery 40 can be a lithium ion battery. The battery 40 can include a cathode 42, an anode 48, an electrolyte 44, and a separator 46. The cathode 42 can be chosen from at least one of lithium, Li, lithium iron phosphate (LiFePO₄), lithium manganese oxide (LiMnO₂), and lithium cobalt oxide (LiCoO₂). In one example, the cathode 42 is lithium. The anode 48 can be the hybrid carbon nanotube and graphene nanostructure 10 (e.g., hybrid nanostructure 10), as shown in FIG. 1. As discussed above with respect to FIG. 1, the hybrid nanostructure 10 can include the conductive substrate 12, the graphene layer 14 deposited onto the surface of the conductive substrate, and the plurality of carbon nanotubes 16 grown onto the surface 24 of the graphene layer.

In one example, the electrolyte 44 was formed by dissolving 1 molar lithium hexafluorophosphate in a 1:1 (by volume) mixture of ethylene carbonate (EC) and dimethyl carbonate (DMC). However, other electrolytes suitable for use in a lithium ion battery can be used. The separator 46 can include be a porous membrane, such as polyethylene (PE) membrane, polypropylene (PP) membrane, anodic aluminum oxide (AAO) template, block-co-polymer (BCP), and filter paper. Other porous membranes suitable for use in a lithium ion battery can be used.

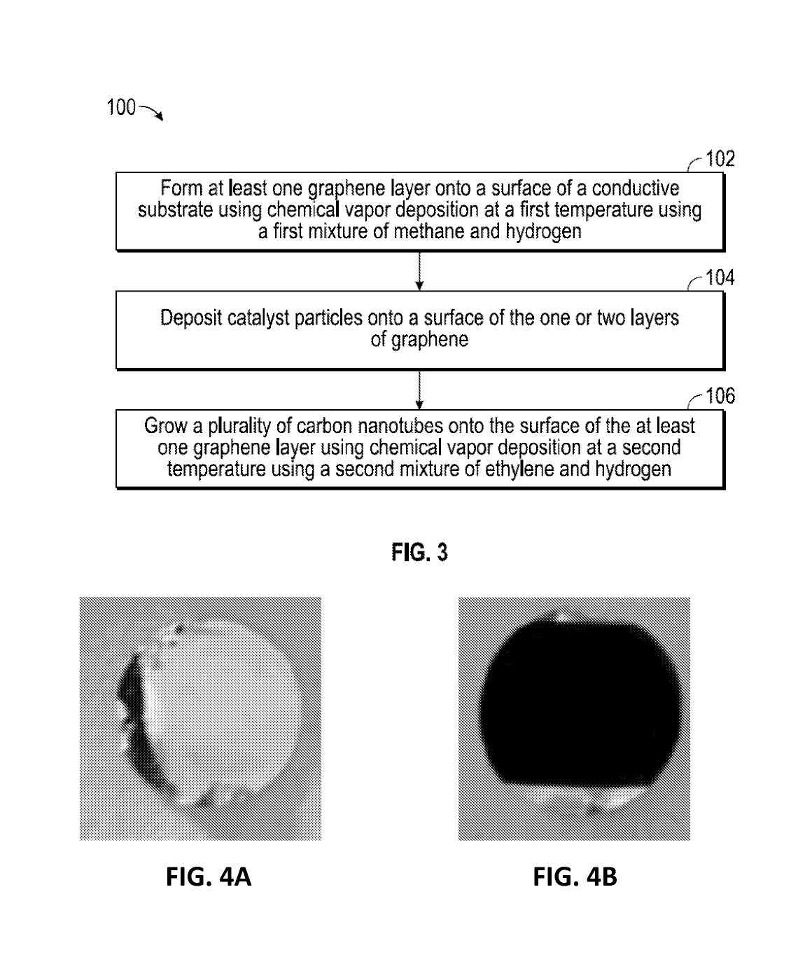

FIG. 3 illustrates generally a flow diagram of a method 100 for forming the hybrid nanostructure 10. As discussed herein, the hybrid nanostructure 10 can be formed by a two-step chemical vapor deposition process. The first step can include forming the graphene layer onto a conductive substrate and the second step can include growing pillar carbon nanotubes on a surface of the graphene layer.

In an example, method 100, at step 102, can include forming at least one graphene layer onto a surface of a conductive substrate using chemical vapor deposition at a first temperature using a first mixture of methane and hydrogen. In an example, the first temperature can be about 950 degrees Celsius, however, other temperatures from about 600 degrees Celsius to about 1080 degrees Celsius can be used. In an example, the conductive substrate can be positioned within a chamber where the chamber has ambient pressure and an atmosphere of argon/hydrogen gas. Methane can be introduced into the chamber and mix with the hydrogen such that the at least one graphene layer is deposited onto the surface of the conductive substrate. For example, as illustrated in FIG. 1, the graphene layer 14 can be deposited onto a surface of the conductive substrate 12. In an example, the conductive substrate is a copper foil.

In an example, the method 100 can include forming less than twenty graphene layers onto the surface of the conductive substrate. In an example, the method 100 can include forming less than three graphene layers onto the surface of the conductive substrate. For example, one graphene layer or two graphene layers can be formed onto the surface of the conductive substrate. The method 100 can include forming the at least one graphene layer by chemical vapor deposition, for example, an ambient pressure chemical vapor deposition process.

The method 100 can also include cleaning and annealing the conductive substrate prior to forming the at least one graphene layer on the surface of the conductive substrate. Cleaning can remove any contamination and annealing can release any residual stress in the conductive substrate and coarsen the average grain size and flatten the surface.

The method 100, at step 104, can include depositing catalyst particles onto a surface of the at least one graphene layer. In an example, the catalyst particles can be chosen from iron (Fe), nickel (Ni), cobalt (Co), and silicon (Si). In one example, the catalyst particles include a plurality of iron particles. The catalyst particles can have an average diameter within a range of about 1 nm to about 5 nm. The method 100 can include depositing the catalyst particles via electron bean evaporation. The method 100 can include selectively patterning the catalyst particles onto the surface of the one or two graphene layers.

The method 100, at step 106, can include growing a plurality of carbon nanotubes onto the surface of the at least one graphene layer using chemical vapor deposition at a second temperature using a second mixture of ethylene and hydrogen to form a binder-free hybrid carbon nanotube and graphene nanostructure. For example, as illustrated in FIG. 1, the pillar carbon nanotubes 16 can be grown onto a surface 24 of the graphene layer 14. In an example, the second temperature can be within a range of about 500 degrees Celsius to about 900 degrees Celsius, such as 750 degrees Celsius. However, other temperatures can be used. The method 100 can include, after growing the pillar carbon nanotubes is complete, cooling the binder-free hybrid carbon nanotube and graphene nanostructure to about 20 degrees Celsius. As discussed herein, the method 100 can provide optimized growth of carbon nanotubes and graphene structures directly on metal foils such that the graphene and the carbon nanotubes are seamlessly connected without a binder.

### Examples

The following examples are given to illustrate, but not limit, the scope of the present disclosure.

Forming Hybrid Carbon Nanotube and Graphene Nanostructures (“Hybrid Nanostructure”)

A graphene layer including two layers of graphene was formed onto a 20 μm thick copper foil by ambient pressure chemical vapor deposition at 950 degrees Celsius using a mixture of methane and hydrogen. A thin layer of iron particles (e.g., catalyst particles) was deposited onto the graphene layer by electron beam evaporation. Pillar carbon nanotubes were grown by ambient pressure chemical vapor deposition at 750 degrees Celsius using a mixture of ethylene and hydrogen. The growth time was controlled such that the height of the plurality of carbon nanotubes was about 50 μm.

FIG. 4A illustrates a copper foil. The copper foil has a thickness of 20 μm. FIG. 4B illustrates a hybrid nanostructure. That is, a graphene layer is formed onto the copper foil and then the pillar carbon nanotubes are grown onto a surface of the graphene layer to form the hybrid nanostructure. The diameter of the copper foil used in FIGS. 4A-B is about 1.5 centimeters.

Morphology of the Hybrid Nanostructure

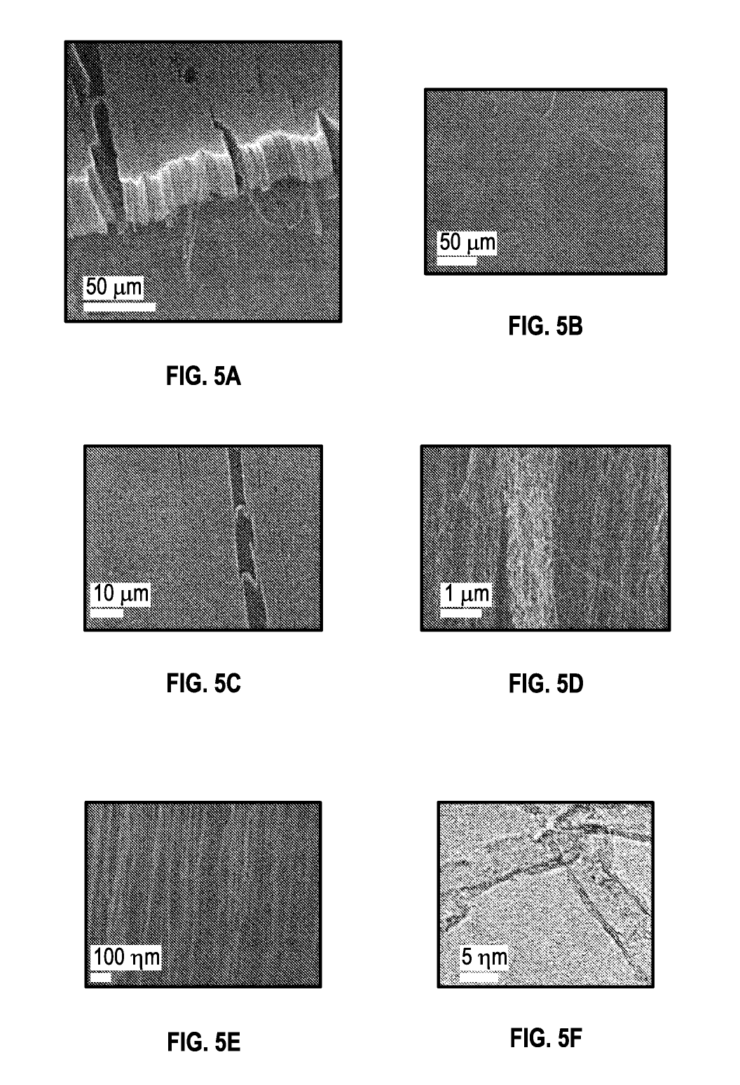

Scanning electron micrograph (SEM) images are shown in FIGS. 5A-F to illustrate the morphology of the hybrid nanostructure. FIG. 5A illustrates an SEM image of the hybrid nanostructure of FIG. 4B. FIG. 5A illustrates neighboring regions of the copper foil and the graphene layer and pillar carbon nanotubes grown onto the copper foil. This distinction can be achieved by selectively pattering catalyst particles on desired regions. As illustrated in FIG. 5A, vertically aligned and densely packed pillar carbon nanotubes are grown on the graphene covered copper foil. FIG. 5B illustrates a top view SEM image of a conductive substrate after a graphene layer has been deposited. FIG. 5B shows a clean, uniform coverage of graphene on the copper foil surface. FIG. 5C illustrates a top view SEM image of a hybrid nanostructure. That is, the pillar carbon nanotubes are grown onto a surface of a graphene layer. As shown in FIG. 5C, the pillar carbon nanotubes have substantial coverage and the upper surface of the pillar carbon nanotubes is substantially flat. FIG. 5D illustrates a cross-sectional view SEM image of FIG. 5C. FIG. 5D shows a low magnification of the curly and densely packed nature of the pillar carbon nanotubes. The curled nature of the pillar carbon nanotubes can increase the number of active sites and can increase properties when the hybrid nanostructure is used in energy storage and conversion applications. FIG. 5E illustrates a close-up view of the SEM image in FIG. 5D. FIG. 5E shows the diameter distribution of the pillar carbon nanotubes. FIG. 5F illustrates the high resolution transmission electron microscopy (HRTEM) of the hybrid nanostructure. As shown in FIG. 5F, it was determined that the pillar carbon nanotubes have an average outer diameter within a range of about 8 nm to about 15 nm, a wall thickness of about 3 layers, and an inner diameter of about 5 nm.

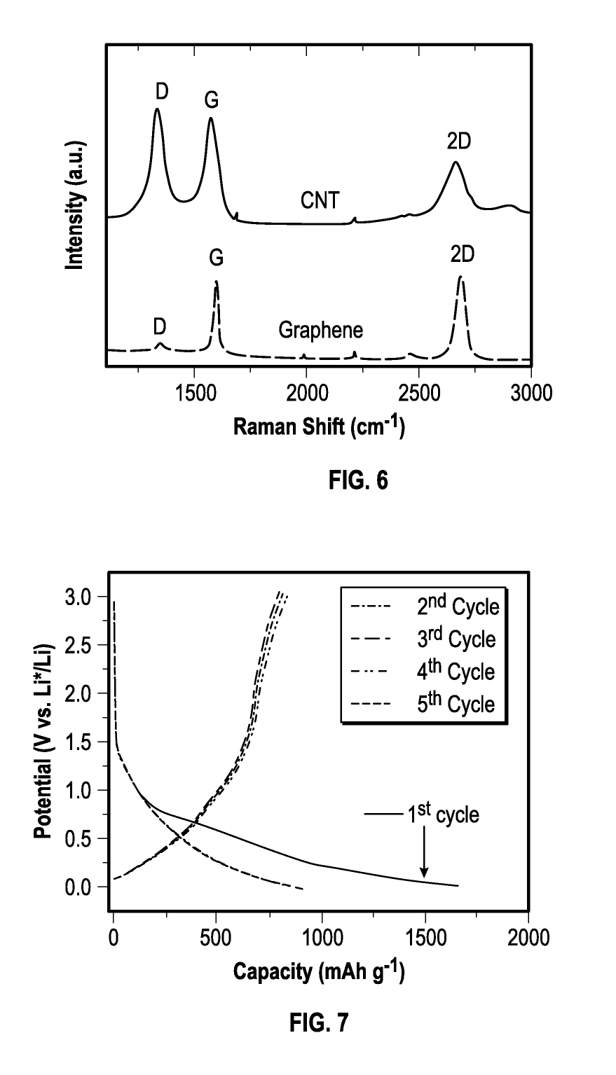

FIG. 6 illustrates a Raman spectra of the hybrid nanostructure. The Raman spectra can further confirm the quality of the hybrid nanostructure. The Raman spectra for the graphene shows the presence of the G peak at 1583 cm⁻¹, the 2D peak at 2679 cm⁻¹, and the G/2D ratio indicate the typical Raman characteristics for double layer graphene sheets. A minor D band is observed at 1335 cm⁻¹, which demonstrates the high quality of the hybrid nanostructure. Raman spectroscopy features collected from the portion of the copper foil including the plurality of carbon nanotubes shows the presence of the intense D band centered around 1338 cm⁻¹, the intensity of which is relatively higher than compared to that of the G band centered around 1571 cm⁻¹. The 2D band for the pillared carbon nanotubes is centered at approximately 2660 cm⁻¹ and is a single peak, which is similar to the 2D band for the graphene. The presence of the intense D band in the spectrum can be associated with defects of the pillared carbon nanotubes such as impurities from the growth, moistures attached on the surface of the plurality of carbon nanotubes, unsaturated bonds, dislocations, etc.

Lithium Ion Battery Assembly

A button-type (CR 2032) two-electrode half-cell configuration (also referred to as “lithium ion battery”) was assembled. The lithium ion battery was assembled in an Argon filled glove box with moisture and oxygen levels below 1 part per million. The hybrid nanostructure was used as the anode and pure lithium metal was used as the counter electrode of the lithium ion battery. A porous membrane (Celgard 3501) was used as the separator. The electrolyte was formed by dissolving 1 molar lithium hexafluorophosphate in a 1:1 volume ratio mixture of ethylene carbonate and dimethyl carbonate. Galvanostatic charge-discharge and cycling performance measurements were conducted at a fixed voltage window between 0.01 Volts (V) and 3.0 V with an Arbin battery tester.

Lithium Ion Battery Testing

FIG. 7 illustrates a voltage profile of the lithium ion battery. FIG. 7 illustrates the voltage profiles as the lithium ion battery was tested with the Arbin battery tester at a current density of 100 milliampere per gram (mA g⁻¹) with a voltage range between 0.01 V and 3.0V for the first five cycles. The hybrid nanostructure (e.g., the anode) exhibits a reversible capacity of 904.52 milliampere hour per gram (mAh g⁻¹) in the 1^{st} cycle. The reversible capacity for the following four cycles are substantially the same. For example, the hybrid nanostructure exhibited a reversible capacity of 897.83 mAh g⁻¹ during the 5^{th} cycle. The charge capacity for the lithium ion battery of the present disclosure is higher as compared to other carbonaceous electrodes. Not to be bound by theory, but the irreversible discharge capacitance for the first discharge can be due to the formation of a solid electrolyte interface/interphase (SEI) layer on the surface of the pillar carbon nanotubes.

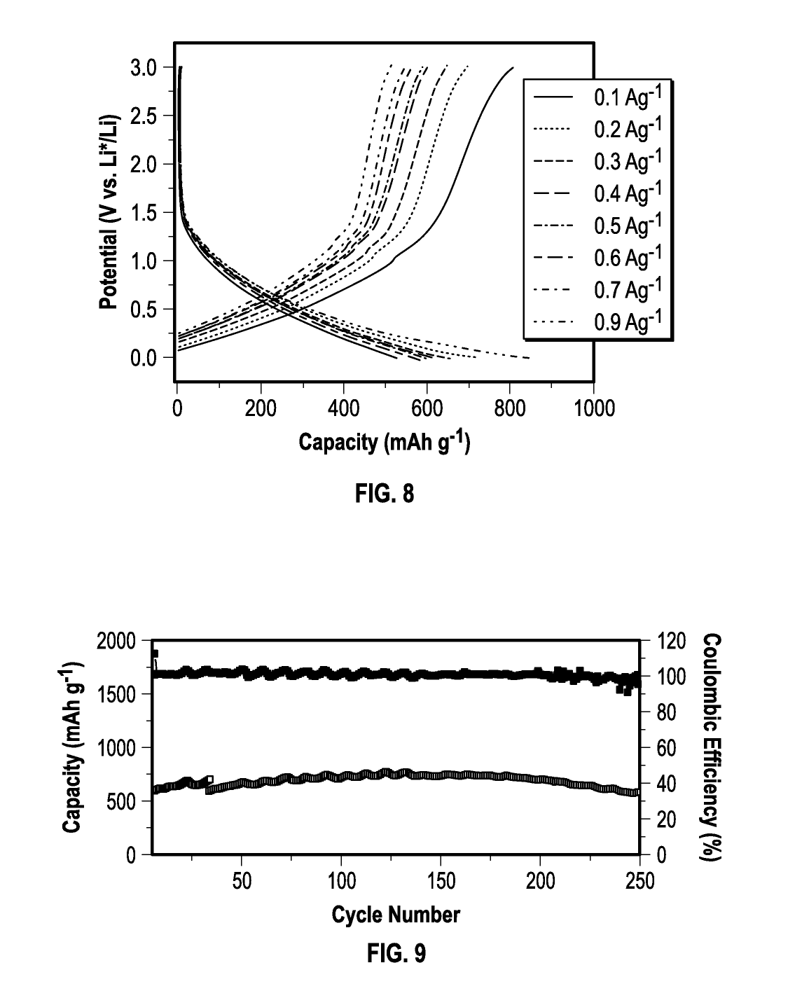

FIG. 8 illustrates a voltage profile of the lithium ion battery. FIG. 8 illustrates the voltage profiles as the lithium ion battery was tested under a range of current densities. With the increase of current density from 100 mA g⁻¹ to 900 mA g⁻¹, the reversible capacity gradually decreased from 900 mAh g⁻¹ to 526.26 mAh g⁻¹, respectively. The decrease in the reversible capacity can be attributed to incompleteness of lithiation and delithiation due to high current density.

To illustrate the high cycling stability of the lithium ion battery utilizing the hybrid nanostructure as the anode, the lithium ion battery was cycled at a current density of 600 mA g⁻¹ for 250 cycles. The results are shown in FIG. 9. FIG. 9 illustrates cycling performance and Coulombic efficiency of the lithium ion battery. As illustrated in FIG. 9, a reversible capacity retention of 98.82% was achieved with approximately 100% Coulombic efficiency.

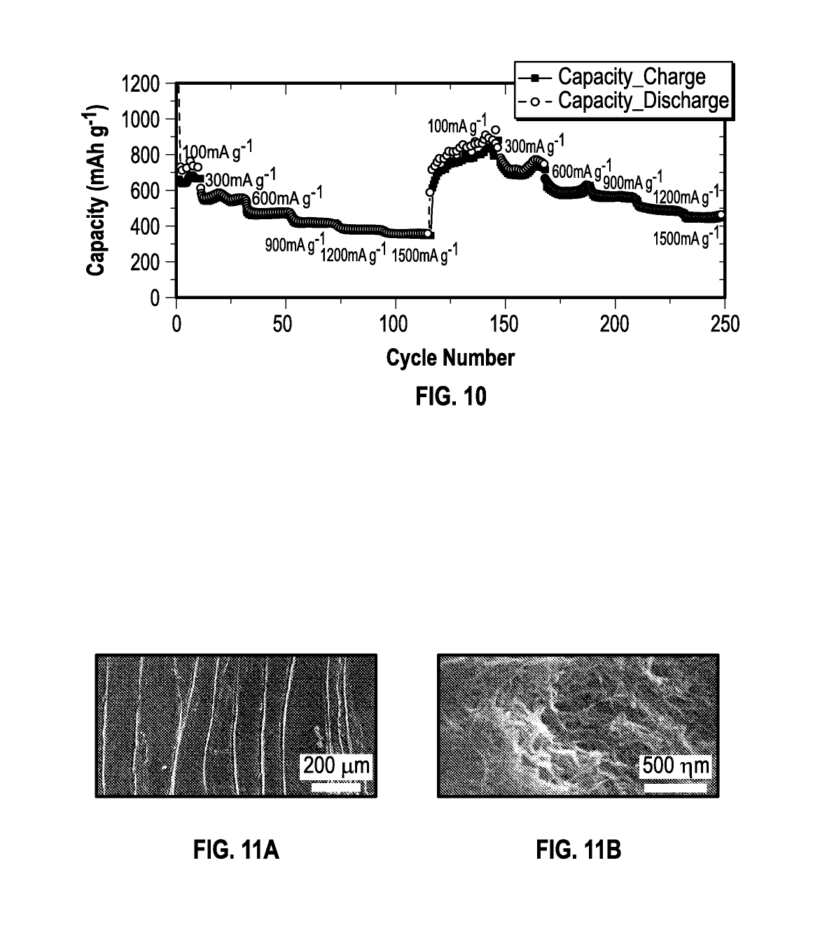

FIG. 10 illustrates the rate performance of the lithium ion battery. With an increase of the charge-discharge current density from 100 mA g⁻¹ to 1500 mA g⁻¹, the capacity decreases from about 900 mAh g⁻¹ to about 370 mA g⁻¹, respectively. In the second round of rate performance cycling testing, a slight increase of capacity (e.g., about 20%) was observed, indicating a very good cycling rate performance and electrochemical stability of the hybrid nanostructure electrode.

The lithium ion battery was disassembled in the discharged state after 250 charge-discharge cycles. The hybrid nanostructure was removed and rinsed repeatedly with a mixture of ethylene carbonate and dimethyl carbonate in a glove box. FIGS. 11A and 11B illustrate SEM images of the cycled hybrid nanostructure. FIG. 11A illustrates a top view low magnification SEM of the cycled hybrid nanostructure and FIG. 11B illustrates a top view high magnification SEM of the cycled hybrid nanostructure. As suggested by FIG. 11A, the hybrid nanostructure still had integrity and remained well-attached to the copper surface. The wrinkles on the surface of the hybrid nanostructure can be due to the wetting of the pillar carbon nanotubes and the compression force applied in the assembled button-type battery cell. As illustrated in FIG. 11B, the porous network morphology is maintained, where the pillar carbon nanotubes are still clearly distinguishable. The pillar carbon nanotubes can bundle together after cycling, and the average diameter can increase dramatically from 10 mm to about 20-30 nm. The reason for the enlargement of the pillar carbon nanotube is due to the formation of the SEI layer on the pillar carbon nanotube surface.

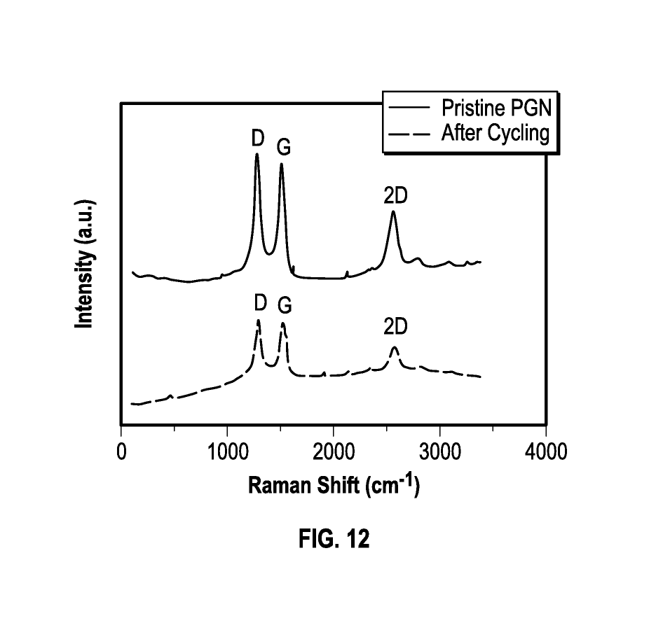

FIG. 12 illustrates a comparison of the Raman spectra before and after cycling for the hybrid nanostructure. After normalizing of the G peak, no obvious changes were observed for the intensity of the D and G peaks, which further confirm the high stability of the hybrid nanostructures of the present disclosure for high stability anodes in rechargeable lithium ion batteries.

As discussed herein, the method disclosed herein can provide a binder-free technique for forming hybrid nanostructures that can be used in lithium ion batteries. The hybrid nanostructure of the present disclosure can have a reversible capacity of 900 mAh g⁻¹, which is higher than other graphitic systems including vertically aligned carbon nanotubes. The hybrid nanostructure of the present disclosure illustrated a high cycling stability. For example, the hybrid nanostructure exhibited about 99% capacity retention with about 100% Coulombic efficiency over 250 cycles, while the hybrid nanostructure maintains the porous network nature after the charge-discharge cycles.

### Various Notes & Examples

To further describe the methods and hybrid carbon nanotube and graphene nanostructures disclosed herein, a non-limiting list of examples is provided here:

In Example 1, a method, comprises forming at least one graphene layer onto a surface of a conductive substrate using chemical vapor deposition at a first temperature using a first mixture of methane and hydrogen, depositing catalyst particles onto a surface of the at least one graphene layer, and growing a plurality of carbon nanotubes onto the surface of the at least one graphene layer using chemical vapor deposition at a second temperature using a second mixture of ethylene and hydrogen to form a binder-free hybrid carbon nanotube and graphene nanostructure.

In Example 2, the subject matter of Example 1 can optionally be configured to include forming less than three graphene layers onto the surface of the conductive substrate.

In Example 3, the subject matter of any one or any combination of Examples 1 or 2 can optionally be configured to include forming two graphene layers onto the surface of the conductive substrate.

In Example 4, the subject matter of any one or any combination of Examples 1 through 3 can optionally be configured such that the first temperature is 950 degrees Celsius.

In Example 5, the subject matter of any one or any combination of Examples 1 through 4 can optionally be configured such that the second temperature is 750 degrees Celsius.

In Example 6, the subject matter of any one or any combination of Examples 1 through 5 can optionally be configured such that the chemical vapor deposition is an ambient pressure chemical vapor deposition process.

In Example 7, the subject matter of any one or any combination of Examples 1 through 6 can optionally be configured to include annealing the conductive substrate prior to forming the at least one graphene layer onto the surface of the conductive substrate.

In Example 8, the subject matter of any one or any combination of Examples 1 through 7 can optionally be configured such that the conductive substrate is a copper foil.

In Example 9, the subject matter of any one or any combination of Examples 1 through 8 can optionally be configured such that the catalyst particles include a plurality of iron particles.

In Example 10, the subject matter of any one or any combination of Examples 1 through 9 can optionally be configured such that the plurality of iron particles have an average diameter within a range of about 1 nanometer to about 5 nanometers.

In Example 11, the subject matter of any one or any combination of Examples 1 through 10 can optionally be configured such that depositing the catalyst particles is done via electron bean evaporation.

In Example 12, the subject matter of any one or any combination of Examples 1 through 11 can optionally be configured such that depositing the catalyst particles comprises selectively patterning the catalyst particles onto the surface of the at least one graphene layer.

In Example 13, a battery can comprise a cathode and an anode including a conductive substrate, one or two graphene layers deposited onto a surface of the conductive substrate, and a plurality of carbon nanotubes grown onto a surface of the graphene layer. The battery can include an electrolyte and a separator positioned between the cathode and anode.

In Example 14, the subject matter of any one or any combination of Examples 1 through 13 can optionally be configured such that the battery is a lithium-ion battery.

In Example 15, the subject matter of any one or any combination of Examples 1 through 14 can optionally be configured such that the anode is free from a binder.

In Example 16, the subject matter of any one or any combination of Examples 1 through 15 can optionally be configured such that the conductive substrate is chosen from at least one of as copper, nickel, and aluminum.

In Example 17, the subject matter of any one or any combination of Examples 1 through 16 can optionally be configured such that the conductive substrate is a copper foil.

In Example 18, an energy device comprises a conductive substrate, at least one graphene layer deposited onto a surface of the conductive substrate, and a plurality of carbon nanotubes grown onto a surface of the graphene layer, wherein the energy device does not include a binder.

In Example 19, the subject matter of any one or any combination of Examples 1 through 18 can optionally be configured such that the conductive substrate is a copper foil.

In Example 20, the subject matter of any one or any combination of Examples 1 through 19 can optionally be configured such that the at least one graphene layer is less than three graphene layers.

In Example 21, the subject matter of any one or any combination of Examples 1 through 20 can optionally be configured such that a battery including the binder-free hybrid carbon nanotube and graphene nanostructure has a reversible capacity of 900 mAh g⁻¹.

In Example 22, the subject matter of any one or any combination of Examples 1 through 21 can optionally be configured such that the battery including the binder-free hybrid carbon nanotube and graphene nanostructure has about 99% capacity retention and about 100% Coulombic efficiency over 250 cycles.

These non-limiting examples can be combined in any permutation or combination. The above Detailed Description is intended to be illustrative, and not restrictive. For example, the above-described examples (or one or more elements thereof) can be used in combination with each other. Other embodiments can be used, such as by one of ordinary skill in the art upon reviewing the above description. Also, various features or elements can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

In the application, the terms “including” and “in which” are used as the plain-English equivalents of the respective terms “comprising” and “wherein.” Also, in the following claims, the terms “including” and “comprising” are open-ended, that is, a method, a battery, or an energy device that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” should be interpreted to include not just 0.1% to 5%, inclusive, but also the individual values (e.g., 1%, 2%, 3%, and 4%) and the sub-ranges (e.g., 0.1% to 0.5%, 1.1% to 2.2%, 3.3% to 4.4%) within the indicated range. As used herein, the term “about” can be defined to include a margin of error, for example, at least +/−10%.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A method, comprising:
forming at least one graphene layer onto a surface of a conductive substrate using chemical vapor deposition at a first temperature using a first mixture including methane and hydrogen;
depositing catalyst particles onto a surface of the at least one graphene layer; and
growing a plurality of carbon nanotubes onto the surface of the at least one graphene layer using chemical vapor deposition at a second temperature using a second mixture of ethylene and hydrogen to form a binder-free hybrid carbon nanotube and graphene nanostructure.

2. The method of claim 1, comprising forming less than three graphene layers onto the surface of the conductive substrate.

3. The method of claim 1, comprising forming two graphene layers onto the surface of the conductive substrate.

4. The method of claim 1, wherein the first temperature is about 950 degrees Celsius.

5. The method of claim 1, wherein the second temperature is about 750 degrees Celsius.

6. The method of claim 1, wherein the chemical vapor deposition is an ambient pressure chemical vapor deposition process.

7. The method of claim 1, comprising annealing the conductive substrate prior to forming the at least one graphene layer onto the surface of the conductive substrate.

8. The method of claim 1, wherein the conductive substrate is a copper foil.

9. The method of claim 1, wherein the catalyst particles include a plurality of iron particles.

10. The method of claim 9, wherein the plurality of iron particles have an average diameter within a range of about 1 nanometer to about 5 nanometers.

11. The method of claim 1, wherein depositing the catalyst particles is done via electron bean evaporation.

12. The method of claim 1, wherein depositing the catalyst particles comprises selectively patterning the catalyst particles onto the surface of the at least one graphene layer.

13. A battery, comprising
a cathode;
an anode, including:
a conductive substrate,
one or two graphene layers deposited onto a surface of the conductive substrate, and
a plurality of carbon nanotubes grown onto a surface of the graphene layer;
an electrolyte; and
a separator positioned between the cathode and anode.

14. The battery of claim 13, wherein the battery is a lithium-ion battery.

15. The battery of claim 13, wherein the anode is free from a binder.

16. The battery of claim 13, wherein the conductive substrate is chosen from at least one of as copper, nickel, and aluminum.

17. The battery of claim 13, wherein the conductive substrate is a copper foil.

18. A energy device, comprising
a conductive substrate;
at least one graphene layer deposited onto a surface of the conductive substrate; and
a plurality of carbon nanotubes grown onto a surface of the graphene layer, wherein the energy device does not include a binder.

19. The energy device of claim 18, wherein the conductive substrate is a copper foil.

20. The energy device of claim 18, wherein the at least one graphene layer is less than three graphene layers.
